(19) United States
(12) Patent Application Publication
(10) Pub. No.: US 2003/0030056 A1
(43) Pub. Date: Feb. 13, 2003

(54) Voltage and current reference circuits using different substrate-type components

(75) Inventor: Edgar H. Callaway JR., Boca Raton, FL (US)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MOTOROLA, INC., Schaumburg, IL (US)

(21) Appl. No.: 09/921,898

(22) Filed: Aug. 6, 2001

(51) Int. Cl. H01L 31/0256

(52) U.S. Cl. 257/76

(57) ABSTRACT

Reference circuits are provided that include circuit components formed from both a composite semiconductor and silicon on a single integrated circuit. The reference circuits provide a reference current that is a function of the threshold voltage of the compound semiconductor device. The reference circuits may include, for example, a HEMT formed on a gallium arsenide layer, which overlays at least a portion of a silicon substrate. A MOSFET formed on the silicon substrate is coupled to the HEMT through a current mirror so that both devices are coupled to receive current based on a common current. Each device is coupled to one input of an error amplifier that provides an output signal that adjusts the common current.

### BACKGROUND OF THE INVENTION

This invention generally relates to semiconductor structures and devices and to a method for their fabrication. More particularly, this invention relates to improving the performance of voltage and current reference circuits by utilizing components formed from semiconductor devices of two different semiconductor types. For example, the present invention provides improved performance in reference circuits where one device is based on a compound semiconductor, such as gallium arsenide, and the other is based on silicon.

Voltage and current reference circuits have a wide range of applications. For example, voltage and current reference circuits may be used in voltmeters, calibrators, scales, RF oscillators, analog-to-digital converters, digital-to-analog converters, as well as for a variety of low noise and/or low power applications. Most of these applications, however, often utilize silicon substrate-based integrated circuits which provide predictable performance over a broad range of temperature.

In addition to silicon-based integrated circuits, it is well known that there are a variety of applications where, for example, gallium arsenide is utilized as the basis for the circuits. In particular, radio frequency (RF), microwave and optical circuits are particularly well-suited for gallium arsenide instead of silicon, at least in part because of the superior electron transport properties of gallium arsenide, e.g., high electron mobility. Higher mobility leads to a higher current, transconductance, and gain-bandwidth product of the devices. Thus, the advantages of using gallium arsenide substrates over traditional silicon substrates include higher switching speeds, higher operating frequencies, and low parasitic capacitances.

Circuits for these particular applications are often constructed with HEMTs (High Electron Mobility Transistors) or MESFETs (Metal-Semiconductor Field Effect Transistors) instead of conventional silicon-based BJTs (Bipolar Junction Transistors) or MOSFETs (Metal-Oxide Field Effect Transistors). Typically, MESFETs are fabricated on these GaAs substrates because performance of silicon-based MOSFETs suffers at high frequencies (due to the lower electron mobility of silicon).

For example, in low voltage, low power RF applications, it is often desirable to utilize enhancement-mode gallium arsenide HEMTs to achieve good RF performance. Such devices often have a wide variation in threshold voltage. The threshold voltage may vary significantly over environmental conditions, from die-to-die on the same wafer, and from wafer-to-wafer, as well as evidencing some variation from device-to-device on the same die. Conventional tracking techniques, such as current mirrors, and the use of identical devices to bias the active circuit, are of limited value because of the wide variation. Moreover, in these applications, the use of additional devices placed in series, for example, silicon MOSFETs, where threshold variation is significantly narrower, is impracticable because of the low supply voltage.

Accordingly, it would therefore be desirable to provide a silicon-based voltage reference circuit that is representative of a gallium arsenide-based threshold voltage.

It would also be desirable to provide a silicon-based current reference circuit that is representative of a gallium arsenide-based threshold voltage.

It would be still further desirable to provide reference circuits that have particular variations over temperature.

### BRIEF DESCRIPTION OF THE DRAWINGS

FIGS. 1, 2, and 3 illustrate schematically, in cross section, device structures that can be used in accordance with various embodiments of the invention.

FIG. 4 illustrates graphically the relationship between maximum attainable film thickness and lattice mismatch between a host crystal and a grown crystalline overlayer.

FIG. 5 is a high resolution Transmission Electron Micrograph (TEM) of illustrative semiconductor material manufactured in accordance with what is shown herein.

FIG. 6 is an x-ray diffraction taken on an illustrative semiconductor structure manufactured in accordance with what is shown herein.

FIG. 7 illustrates a high resolution Transmission Electron Micrograph of a structure including an amorphous oxide layer.

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13-16 illustrate a probable molecular bonding structure of the device structures illustrated in FIGS. 9-12;

FIGS. 17-20 illustrate schematically, in cross-section, the formation of a device structure in accordance with still another embodiment of the invention; and

FIGS. 21-23 illustrate schematically, in cross-section, the formation of yet another embodiment of a device structure in accordance with the invention.

FIGS. 24, 25 illustrate schematically, in cross section, device structures that can be used in accordance with various embodiments of the invention.

FIGS. 26-30 include illustrations of cross-sectional views of a portion of an integrated circuit that includes a compound semiconductor portion, a bipolar portion, and an MOS portion in accordance with what is shown herein.

FIGS. 31-37 include illustrations of cross-sectional views of a portion of another integrated circuit that includes a semiconductor laser and a MOS transistor in accordance with what is shown herein.

FIG. 38 is a schematic diagram of a model amplifier application circuit.

FIGS. 39 and 40 are schematic diagrams of conventional amplifier bias circuits.

FIG. 41 is a schematic diagram of a reference circuit in accordance with a preferred embodiment of the present invention.

FIG. 42 is a graph of current versus voltage for a typical high electron mobility transistor (HEMT) and a typical metal oxide field effect transistor (MOSFET)

FIGS. 43 and 44 are mechanical diagrams illustrating an integrated circuit that includes the reference circuit in accordance with a preferred embodiment of the present invention.

FIG. 45 is a flow chart showing steps of a method of making a reference circuit on a monocrystalline semiconductor substrate, in accordance with a preferred embodiment of the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

The present invention involves semiconductor structures of particular types.

For convenience herein, these semiconductor structures are sometimes referred to as “composite semiconductor structures” or “composite integrated circuits” because they include two (or more) significantly different types of semiconductor devices in one integrated structure or circuit. For example, one of these two types of devices may be silicon-based devices such as CMOS devices, and the other of these two types of devices may be compound semiconductor devices such GaAs devices.

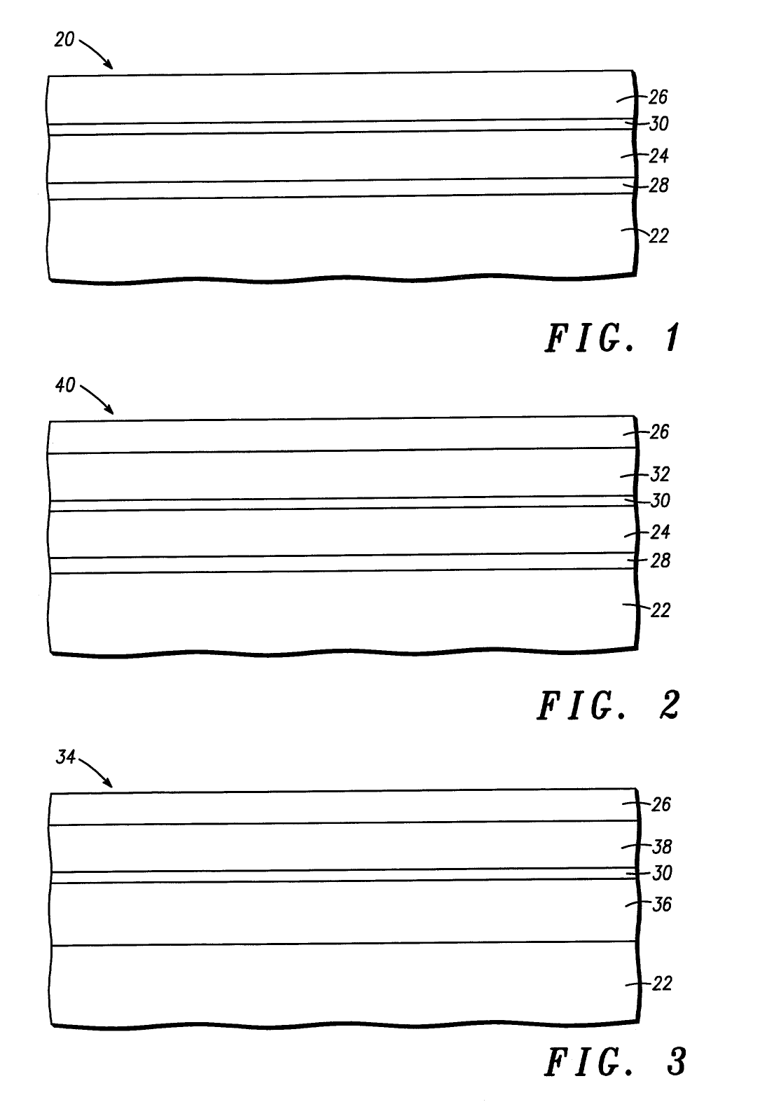

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxide or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II(A or B) and VIA elements (II-VI semiconductor compounds), and mixed II-VI compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer is then exposed to an anneal process to convert the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides a true compliant substrate for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV or monocrystalline compound semiconductor materials.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate oriented in the (100) direction. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by capping the oxide layer. The template layer is preferably 1-10 monolayers of Ti—As, Sr—O—As, Sr—Ga—O, or Sr—Al—O. By way of a preferred example, 1-2 monolayers of Ti—As or Sr—Ga—O have been illustrated to successfully grow GaAs layers.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 5 nm to ensure adequate crystalline and surface quality and is formed of a monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a 45 degree rotation with respect to the substrate silicon lattice structure.

An accommodating buffer layer formed of these zirconate or hafnate materials is suitable for the growth of a monocrystalline material layer which comprises compound semiconductor materials in the indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is 1-10 monolayers of zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 1-2 monolayers of one of these materials. By way of an example, for a barium zirconate accommodating buffer layer, the surface is terminated with 1-2 monolayers of zirconium followed by deposition of 1-2 monolayers of arsenic to form a Zr—As template. A monocrystalline layer of the compound semiconductor material from the indium phosphide system is then grown on the template layer. The resulting lattice structure of the compound semiconductor material exhibits a 45 degree rotation with respect to the accommodating buffer layer lattice structure and a lattice mismatch to (100) InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 5-15 nm. Where the monocrystalline layer comprises a compound semiconductor material, the II-VI compound semiconductor material can be, for example, zinc selenide (ZnSe) or zinc sulfur selenide (ZnSSe). A suitable template for this material system includes 1-10 monolayers of zinc-oxygen (Zn—O) followed by 1-2 monolayers of an excess of zinc followed by the selenidation of zinc on the surface. Alternatively, a template can be, for example, 1-10 monolayers of strontium-sulfur (Sr—S) followed by the ZnSeS.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The template for this structure can be the same of that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about one monolayer can be used as a nucleating site for the subsequent growth of the monocrystalline material layer which in this example is a compound semiconductor material. The formation of the oxide layer is capped with either a monolayer of strontium or a monolayer of titanium to act as a nucleating site for the subsequent deposition of the monocrystalline germanium. The monolayer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0 to about 50%. The additional buffer layer 32 preferably has a thickness of about 10-30 nm. Varying the composition of the buffer layer from GaAs to InGaAs serves to provide a lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1),which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 2 nm to about 100 nm, preferably about 2-10 nm, and more preferably about 5-6 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 monolayer to about 100 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

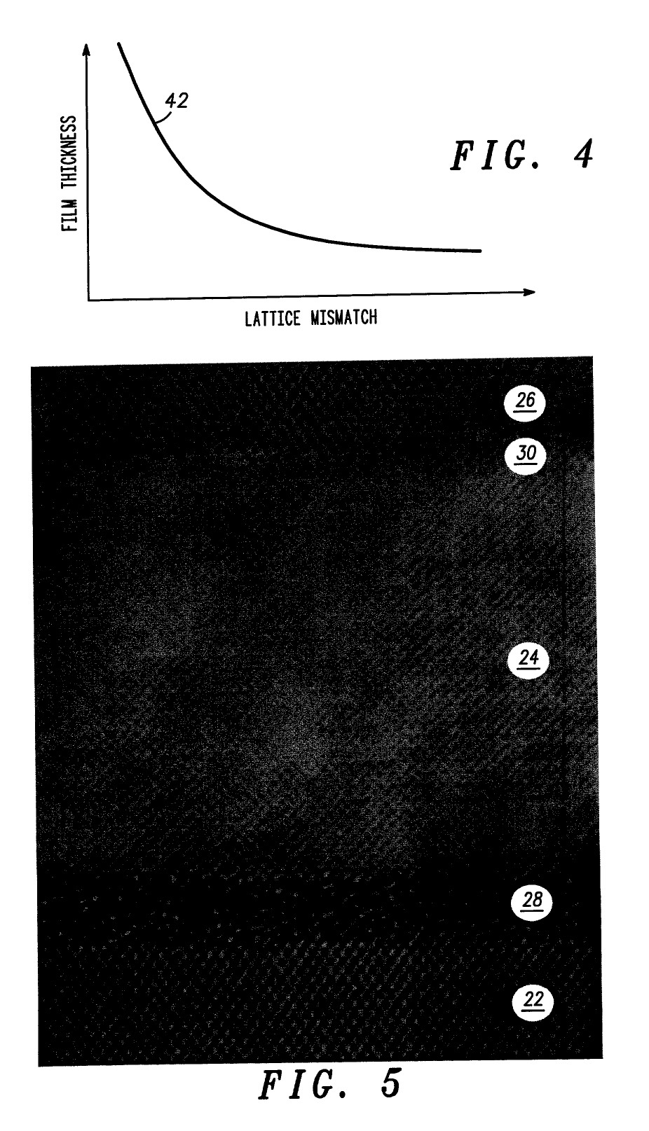

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is a (100) or (111) oriented monocrystalline silicon wafer and accommodating buffer layer 24 is a layer of strontium barium titanate. Substantial matching of lattice constants between these two materials is achieved by rotating the crystal orientation of the titanate material by 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by 45° with respect to the host oxide crystal. In some instances, a crystalline semiconductor buffer layer between the host oxide and the grown monocrystalline material layer can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is preferably oriented on axis or, at most, about 4° off axis. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer of strontium, barium, a combination of strontium and barium, or other alkaline earth metals or combinations of alkaline earth metals in an MBE apparatus. In the case where strontium is used, the substrate is then heated to a temperature of about 750° C. to cause the strontium to react with the native silicon oxide layer. The strontium serves to reduce the silicon oxide to leave a silicon oxide-free surface. The resultant surface, which exhibits an ordered 2×1 structure, includes strontium, oxygen, and silicon. The ordered 2×1 structure forms a template for the ordered growth of an overlying layer of a monocrystalline oxide. The template provides the necessary chemical and physical properties to nucleate the crystalline growth of an overlying layer.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of about 750° C. At this temperature a solid state reaction takes place between the strontium oxide and the native silicon oxide causing the reduction of the native silicon oxide and leaving an ordered 2×1 structure with strontium, oxygen, and silicon remaining on the substrate surface. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-800° C. and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.3-0.5 nm per minute. After initiating growth of the strontium titanate, the partial pressure of oxygen is increased above the initial minimum value. The overpressure of oxygen causes the growth of an amorphous silicon oxide layer at the interface between the underlying substrate and the growing strontium titanate layer. The growth of the silicon oxide layer results from the diffusion of oxygen through the growing strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with 1-2 monolayers of titanium, 1-2 monolayers of titanium-oxygen or with 1-2 monolayers of strontium-oxygen. Following the formation of this capping layer, arsenic is deposited to form a Ti—As bond, a Ti—O—As bond or a Sr—O—As. Any of these form an appropriate template for deposition and formation of a gallium arsenide monocrystalline layer. Following the formation of the template, gallium is subsequently introduced to the reaction with the arsenic and gallium arsenide forms. Alternatively, gallium can be deposited on the capping layer to form a Sr—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed which relieves strain due to lattice mismatch. GaAs compound semiconductor layer 26 was then grown epitaxially using template layer 30.

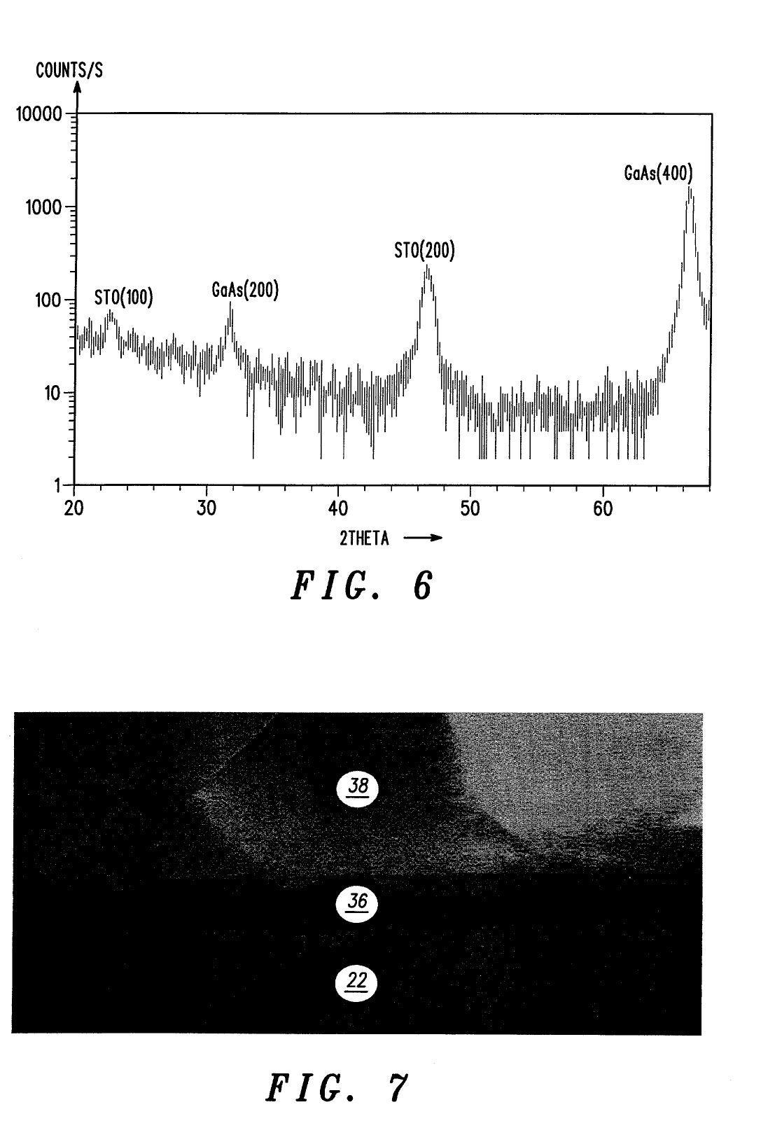

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) orientated.

The structure illustrated in FIG. 2 can be formed by the process discussed above with the addition of an additional buffer layer deposition step. The additional buffer layer 32 is formed overlying the template layer before the deposition of the monocrystalline material layer. If the buffer layer is a monocrystalline material comprising a compound semiconductor superlattice, such a superlattice can be deposited, by MBE for example, on the template described above. If instead the buffer layer is a monocrystalline material layer comprising a layer of germanium, the process above is modified to cap the strontium titanate monocrystalline layer with a final layer of either strontium or titanium and then by depositing germanium to react with the strontium or titanium. The germanium buffer layer can then be deposited directly on this template.

Structure 34, illustrated in FIG. 3, may be formed by growing an accommodating buffer layer, forming an amorphous oxide layer over substrate 22, and growing semiconductor layer 38 over the accommodating buffer layer, as described above. The accommodating buffer layer and the amorphous oxide layer are then exposed to an anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer, the amorphous oxide layer, and monocrystalline layer 38 to a rapid thermal anneal process with a peak temperature of about 700° C. to about 1000° C. and a process time of about 5 seconds to about 10 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 30 may be required to prevent degradation of layer 38 during the anneal process. For example, when layer 38 includes GaAs, the anneal environment preferably includes an overpressure of arsenic to mitigate degradation of layer 38.

As noted above, layer 38 of structure 34 may include any materials suitable for either of layers 32 or 26. Accordingly, any deposition or growth methods described in connection with either layer 32 or 26, may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

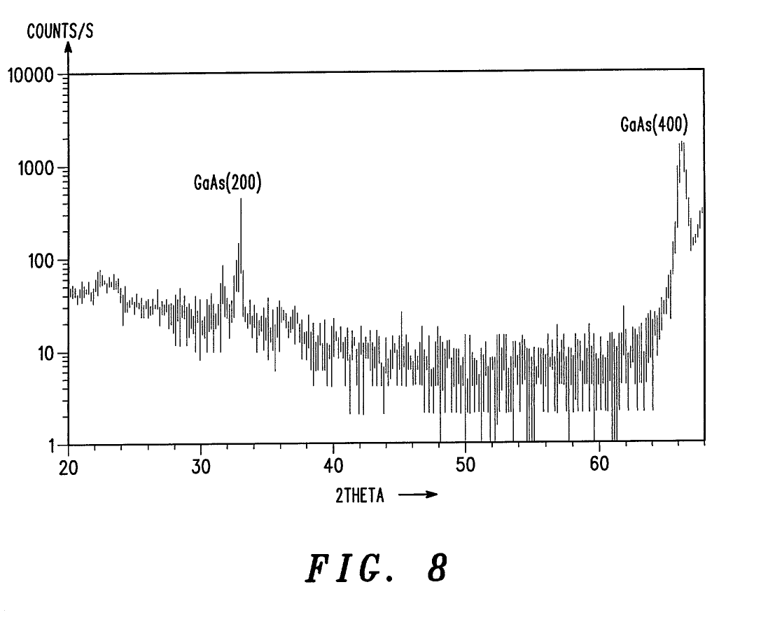

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) orientated and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, and niobates alkaline earth metal tin-based perovskites, lanthanum aluminate, lanthanum scandium oxide, and gadolinium oxide can also be grown. Further, by a similar process such as MBE, other monocrystalline material layers comprising other III-V and II-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

The formation of a device structure in accordance with another embodiment of the invention is illustrated schematically in cross-section in FIGS. 9-12. Like the previously described embodiments referred to in FIGS. 1-3, this embodiment of the invention involves the process of forming a compliant substrate utilizing the epitaxial growth of single crystal oxides, such as the formation of accommodating buffer layer 24 previously described with reference to FIGS. 1 and 2 and amorphous layer 36 previously described with reference to FIG. 3, and the formation of a template layer 30. However, the embodiment illustrated in FIGS. 9-12 utilizes a template that includes a surfactant to facilitate layer-by-layer monocrystalline material growth.

Turning now to FIG. 9, an amorphous intermediate layer 58 is grown on substrate 52 at the interface between substrate 52 and a growing accommodating buffer layer 54, which is preferably a monocrystalline crystal oxide layer, by the oxidation of substrate 52 during the growth of layer 54. Layer 54 is preferably a monocrystalline oxide material such as a monocrystalline layer of Sr_{z}Ba_{1-z}TiO₃ where z ranges from 0 to 1. However, layer 54 may also comprise any of those compounds previously described with reference layer 24 in FIGS. 1-2 and any of those compounds previously described with reference to layer 36 in FIG. 3 which is formed from layers 24 and 28 referenced in FIGS. 1 and 2.

Layer 54 is grown with a strontium (Sr) terminated surface represented in FIG. 9 by hatched line 55 which is followed by the addition of a template layer 60 which includes a surfactant layer 61 and capping layer 63 as illustrated in FIGS. 10 and 11. Surfactant layer 61 may comprise, but is not limited to, elements such as Al, In and Ga, but will be dependent upon the composition of layer 54 and the overlying layer of monocrystalline material for optimal results. In one exemplary embodiment, aluminum (Al) is used for surfactant layer 61 and functions to modify the surface and surface energy of layer 54. Preferably, surfactant layer 61 is epitaxially grown, to a thickness of one to two monolayers, over layer 54 as illustrated in FIG. 10 by way of molecular beam epitaxy (MBE), although other epitaxial processes may also be performed including chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like.

Surfactant layer 61 is then exposed to a Group V element such as arsenic, for example, to form capping layer 63 as illustrated in FIG. 11. Surfactant layer 61 may be exposed to a number of materials to create capping layer 63 such as elements which include, but are not limited to, As, P, Sb and N. Surfactant layer 61 and capping layer 63 combine to form template layer 60.

Monocrystalline material layer 66, which in this example is a compound semiconductor such as GaAs, is then deposited via MBE, CVD, MOCVD, MEE, ALE, PVD, CSD, PLD, and the like to form the final structure illustrated in FIG. 12.

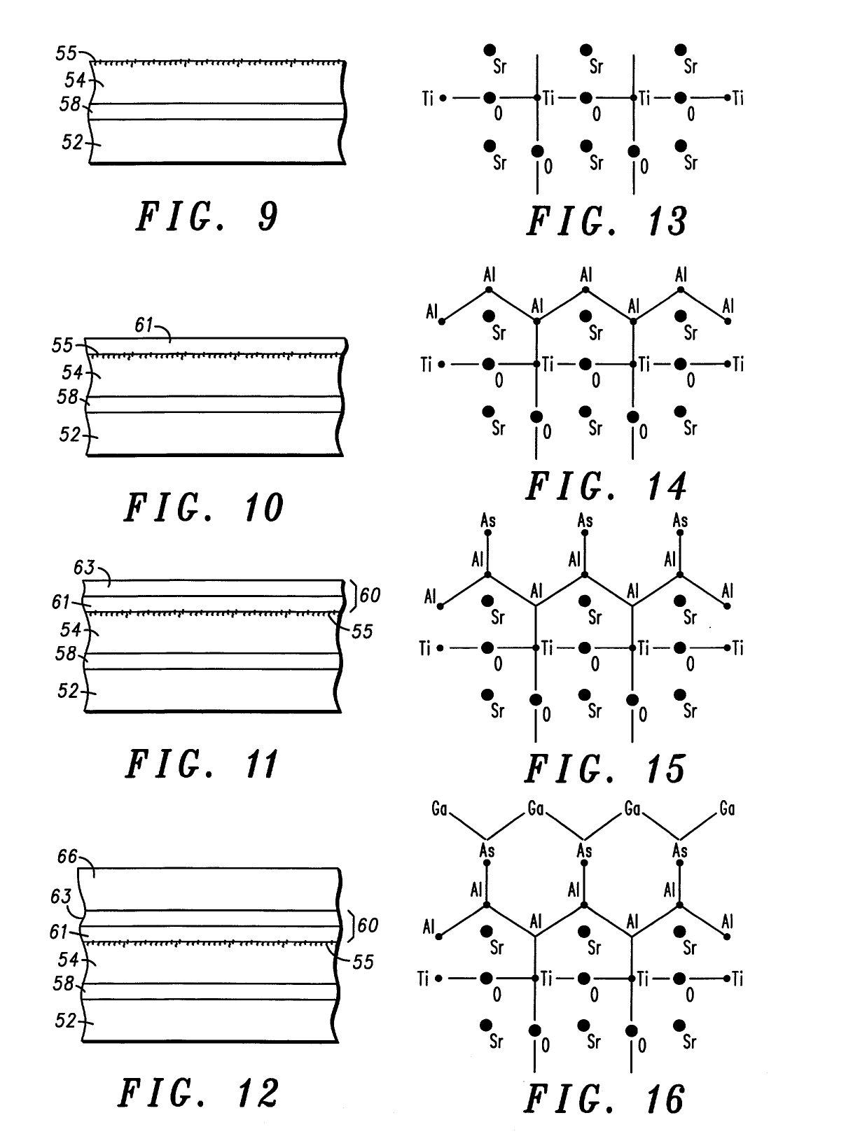

FIGS. 13-16 illustrate possible molecular bond structures for a specific example of a compound semiconductor structure formed in accordance with the embodiment of the invention illustrated in FIGS. 9-12. More specifically, FIGS. 13-16 illustrate the growth of GaAs (layer 66) on the strontium terminated surface of a strontium titanate monocrystalline oxide (layer 54) using a surfactant containing template (layer 60).

The growth of a monocrystalline material layer 66 such as GaAs on an accommodating buffer layer 54 such as a strontium titanium oxide over amorphous interface layer 58 and substrate layer 52, both of which may comprise materials previously described with reference to layers 28 and 22, respectively in FIGS. 1 and 2, illustrates a critical thickness of about 1000 Angstroms where the two-dimensional (2D) and three-dimensional (3D) growth shifts because of the surface energies involved. In order to maintain a true layer by layer growth (Frank Van der Mere growth), the following relationship must be satisfied:

δ_{STO}>(δ_{INT}+δ_{GaAs})

where the surface energy of the monocrystalline oxide layer 54 must be greater than the surface energy of the amorphous interface layer 58 added to the surface energy of the GaAs layer 66. Since it is impracticable to satisfy this equation, a surfactant containing template was used, as described above with reference to FIGS. 10-12, to increase the surface energy of the monocrystalline oxide layer 54 and also to shift the crystalline structure of the template to a diamond-like structure that is in compliance with the original GaAs layer.

FIG. 13 illustrates the molecular bond structure of a strontium terminated surface of a strontium titanate monocrystalline oxide layer. An aluminum surfactant layer is deposited on top of the strontium terminated surface and bonds with that surface as illustrated in FIG. 14, which reacts to form a capping layer comprising a monolayer of Al₂Sr having the molecular bond structure illustrated in FIG. 14 which forms a diamond-like structure with an sp³ hybrid terminated surface that is compliant with compound semiconductors such as GaAs. The structure is then exposed to As to form a layer of AlAs as shown in FIG. 15. GaAs is then deposited to complete the molecular bond structure illustrated in FIG. 16 which has been obtained by 2D growth. The GaAs can be grown to any thickness for forming other semiconductor structures, devices, or integrated circuits. Alkaline earth metals such as those in Group IIA are those elements preferably used to form the capping surface of the monocrystalline oxide layer 54 because they are capable of forming a desired molecular structure with aluminum.

In this embodiment, a surfactant containing template layer aids in the formation of a compliant substrate for the monolithic integration of various material layers including those comprised of Group III-V compounds to form high quality semiconductor structures, devices and integrated circuits. For example, a surfactant containing template may be used for the monolithic integration of a monocrystalline material layer such as a layer comprising Germanium (Ge), for example, to form high efficiency photocells.

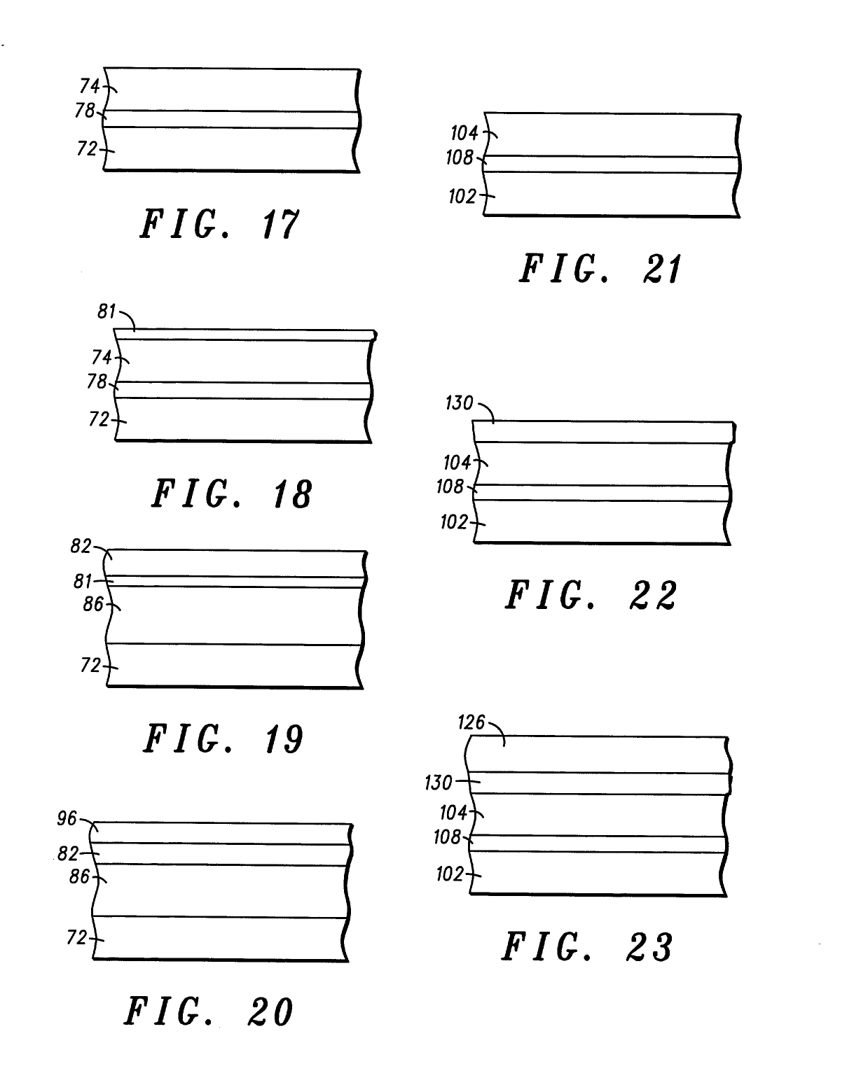

Turning now to FIGS. 17-20, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 17. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, and the like as illustrated in FIG. 18 with a thickness of a few hundred Angstroms but preferably with a thickness of about 50 Angstroms. Monocrystalline oxide layer 74 preferably has a thickness of about 20 to 100 Angstroms.

Rapid thermal annealing is then conducted in the presence of a carbon source such as acetylene or methane, for example at a temperature within a range of about 800° C. to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 19. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, a compound semiconductor layer 96, such as gallium nitride (GaN) is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphosized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature RF applications and optoelectronics. GaN systems have particular use in the photonic industry for the blue/green and UV light sources and detection. High brightness light emitting diodes (LEDs) and lasers may also be formed within the GaN system.

FIGS. 21-23 schematically illustrate, in cross-section, the formation of another embodiment of a device structure in accordance with the invention. This embodiment includes a compliant layer that functions as a transition layer that uses clathrate or Zintl type bonding. More specifically, this embodiment utilizes an intermetallic template layer to reduce the surface energy of the interface between material layers thereby allowing for two dimensional layer by layer growth.

The structure illustrated in FIG. 21 includes a monocrystalline substrate 102, an amorphous interface layer 108 and an accommodating buffer layer 104. Amorphous interface layer 108 is formed on substrate 102 at the interface between substrate 102 and accommodating buffer layer 104 as previously described with reference to FIGS. 1 and 2. Amorphous interface layer 108 may comprise any of those materials previously described with reference to amorphous interface layer 28 in FIGS. 1 and 2. Substrate 102 is preferably silicon but may also comprise any of those materials previously described with reference to substrate 22 in FIGS. 1-3.

A template layer 130 is deposited over accommodating buffer layer 104 as illustrated in FIG. 22 and preferably comprises a thin layer of Zintl type phase material composed of metals and metalloids having a great deal of ionic character. As in previously described embodiments, template layer 130 is deposited by way of MBE, CVD, MOCVD, MEE, ALE, PVD, CSD, PLD, or the like to achieve a thickness of one monolayer. Template layer 130 functions as a “soft” layer with non-directional bonding but high crystallinity which absorbs stress build up between layers having lattice mismatch. Materials for template 130 may include, but are not limited to, materials containing Si, Ga, In, and Sb such as, for example, AlSr₂, (MgCaYb)Ga₂, (Ca,Sr,Eu,Yb)In₂, BaGe₂As, and SrSn₂As₂

A monocrystalline material layer 126 is epitaxially grown over template layer 130 to achieve the final structure illustrated in FIG. 23. As a specific example, an SrAl₂ layer may be used as template layer 130 and an appropriate monocrystalline material layer 126 such as a compound semiconductor material GaAs is grown over the SrAl₂. The Al—Ti (from the accommodating buffer layer of layer of Sr_{z}Ba_{1-z}TiO₃ where z ranges from 0 to 1) bond is mostly metallic while the Al—As (from the GaAs layer) bond is weakly covalent. The Sr participates in two distinct types of bonding with part of its electric charge going to the oxygen atoms in the lower accommodating buffer layer 104 comprising Sr_{z}Ba_{1-z}TiO₃ to participate in ionic bonding and the other part of its valence charge being donated to Al in a way that is typically carried out with Zintl phase materials. The amount of the charge transfer depends on the relative electronegativity of elements comprising the template layer 130 as well as on the interatomic distance. In this example, Al assumes an sp³ hybridization and can readily form bonds with monocrystalline material layer 126, which in this example, comprises compound semiconductor material GaAs.

The compliant substrate produced by use of the Zintl type template layer used in this embodiment can absorb a large strain without a significant energy cost. In the above example, the bond strength of the Al is adjusted by changing the volume of the SrAl₂ layer thereby making the device tunable for specific applications which include the monolithic integration of III-V and Si devices and the monolithic integration of high-k dielectric materials for CMOS technology.

Clearly, those embodiments specifically describing structures having compound semiconductor portions and Group IV semiconductor portions, are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials as well as other material layers that are used to form those devices with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, a relatively inexpensive “handle” wafer overcomes the fragile nature of compound semiconductor or other monocrystalline material wafers by placing them over a relatively more durable and easy to fabricate base material. Therefore, an integrated circuit can be formed such that all electrical components, and particularly all active electronic devices, can be formed within or using the monocrystalline material layer even though the substrate itself may include a monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g. conventional compound semiconductor wafers).

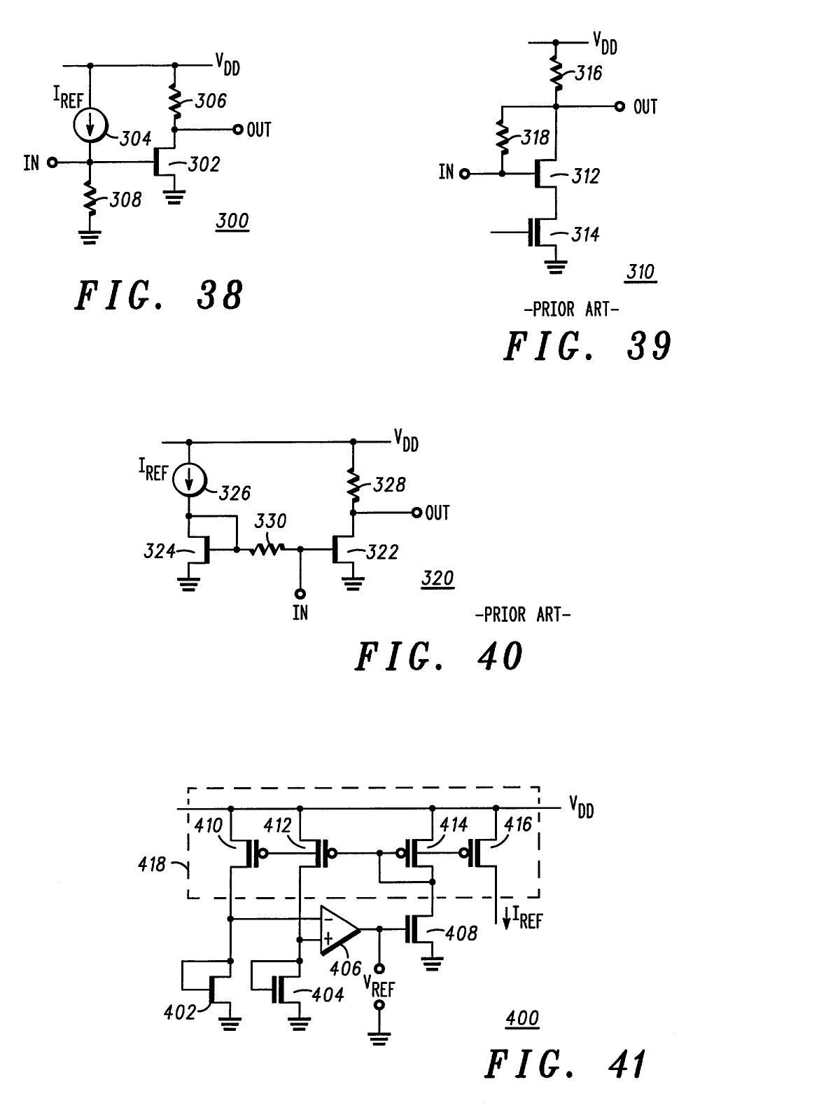

As discussed previously, it would be advantageous to provide, for example, a gallium arsenide-based current reference that is a function of threshold voltage of gallium arsenide devices that have different and varying threshold voltages. FIG. 38 shows a schematic diagram of a model amplifier application circuit 300 that includes high electron mobility transistor (HEMT) 302, current source 304 and resistors 306 and 308. The output of current source 304, I_{ref}, must be a function of the threshold voltage of HEMT 302 for the amplifier 300 to provide a consistent gain. Circuit 300 takes an input signal IN, which is applied to the gate of HEMT 302, and produces an output signal OUT (at the drain of HEMT 302). While the result of circuit 300 is desirable, it is difficult to achieve and replicate using conventional techniques, at least because of the wide threshold variation that exists between different HEMTs, regardless of whether the HEMTs are on the same die or on different dies.

Persons skilled in the art will appreciate that even though the present discussion is directed toward gallium arsenide HEMTs, it is equally applicable to other non-silicon-based circuits as well, such as gallium arsenide, indium phosphide, or gallium nitride MESFETs and pseudomorphic HEMTs. In addition, persons skilled in the art will appreciate that the present invention may be applied to any reference circuit in which one component is formed using one semiconductor material and the other is formed from a different semiconductor material (even if, as described herein, the second semiconductor material is a layer that covers a portion of the first semiconductor material). For example, one component may be a heterojunction bipolar transistor (HBT), while the other component may be a silicon-based bipolar transistor. Thus, for clarity and brevity, the reference circuits discussed herein are focused primarily in the context of circuits employing FETs on compound semiconductors, however, those skilled in the art will appreciate that these techniques may be applied to other semiconductor devices as well.

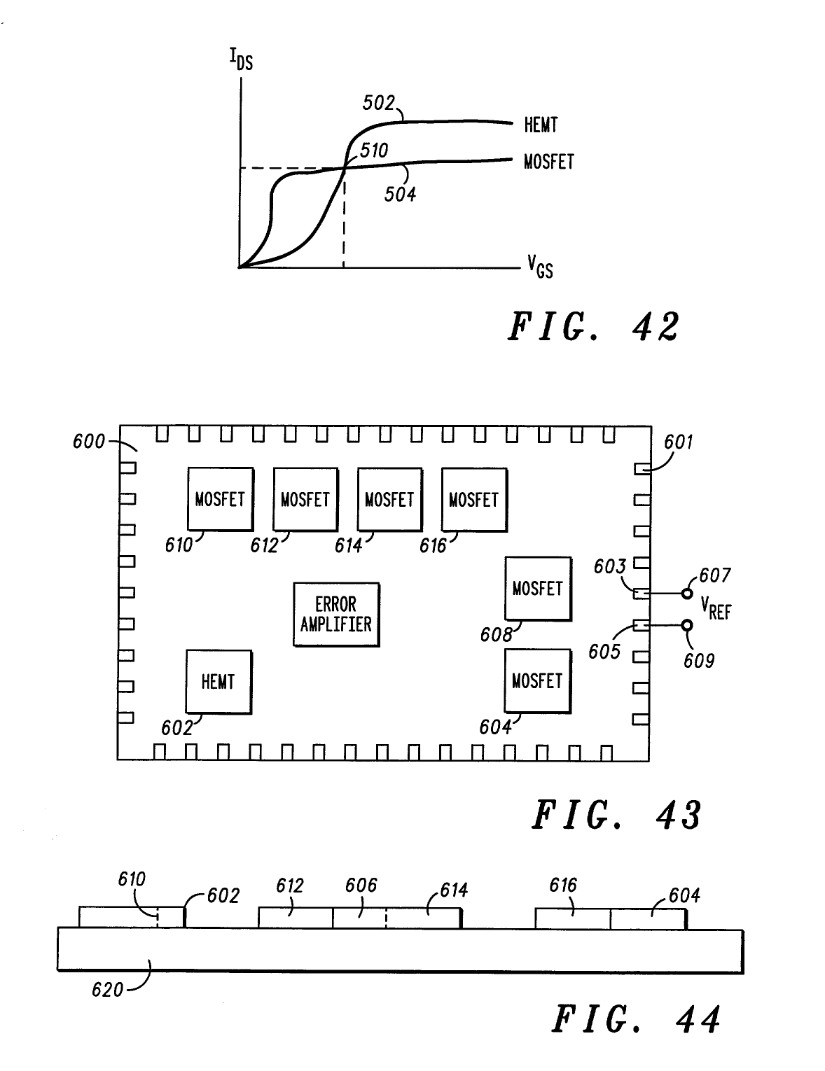

FIGS. 39 and 40 are schematic diagrams of two alternate techniques that are conventionally used to provide transistor bias, but are not practical for low voltage, gallium arsenide applications. In particular, FIG. 39 shows a schematic diagram of a reference circuit 310 that includes HEMT 312, MOSFET 314 and resistors 316 and 318. Circuit 310 takes an input signal IN, which is applied to the gate of HEMT 312, and produces an output signal OUT (at the drain of HEMT 312). The use of MOSFET 314 in circuit 310 is an attempt to benefit from the low threshold variation of the silicon-based MOSFET 314. Unfortunately, however, the series connected MOSFET requires too much of a voltage drop for low supply voltage applications, and doesn't leave enough range for proper operation of the circuit (the overhead of the series-connected MOSFET is simply too high for a low voltage, low power circuit).

Similarly, FIG. 40 shows an alternate technique that is conventionally used to provide reference signals in reference circuit 320. Reference circuit 320 includes HEMT 322, diode-connected HEMT 324, current source 326 (which are coupled together to form a current mirror), output resistor 328 and isolation resistor 330.

Circuit 320 takes an input signal IN, which is applied to the gate of HEMT 322, and produces an output signal OUT (at the drain of HEMT 322). If circuit 320 operated as desired, current passing through current source 326 and diode-connected HEMT 324 would be mirrored in HEMT 322 so that the current passing through HEMT 322 would be a function of the current output by source 326. While such a configuration is useful when it is implemented with silicon-based transistors, the wide variation in threshold voltage of the gallium arsenide-based HEMTs renders circuit 320 ineffective and unpredictable.

FIG. 41 is a schematic diagram of a reference circuit 400 constructed in accordance with the principles of the present invention. In particular, reference circuit 400 includes diode-connected HEMT 402, diode-connected MOSFET 404, error amplifier 406, MOSFET 408, and MOSFETS 410, 412, 414 and 416, which are coupled together to form current mirror 418 (MOSFET 414 is also diode-connected). Persons skilled in the art will appreciate that the term “diode-connected,” as used herein with respect to MOSFETs, simply refers to the fact that the gate and drain electrodes are shorted together (and not that the device operates as a diode, as would be the case with a bipolar transistor or an HEMT). HEMT 402, which may be, for example, an enhancement-mode aluminum gallium arsenide/gallium arsenide (AlGaAs/GaAs) HEMT, receives current from MOSFET 410, while silicon-based MOSFET 404 receives current from MOSFET 412.

The drain current through a silicon-based MOSFET can be expressed as:

$${I}_{DS} = \frac{{μ}_{n} {C}_{ox}}{2} \cdot \frac{W}{L} \cdot {( {V}_{GS} - {V}_{t1} )}^{2} \qquad ( 1 )$$

where:

μₙ is the average electron mobility of the channel;

Cₒₓ is the gate oxide capacitance per unit area;

W is the width of the channel;

L is the length of the channel;

V_{GS} is the gate-source voltage; and

Vₜ₁ is the threshold voltage of the MOSFET.

The drain current through the gallium arsenide-based HEMT, on the other hand, can be expressed as:

I_{DS}=β(V_{GS}−Vₚ)² (2)

where:

β is a dc parameter proportional to the device transconductance;

V_{GS} is the gate-source voltage;

Vₚ is the pinch-off voltage (where Vₚ=Vₜ₂+V_{b});

V_{b} is the built-in voltage; and

Vₜ₂ is the threshold voltage of the HEMT

Reference circuit 400 provides a voltage reference (V_{ref}) from the output of error amplifier 406, which compares the gate-source voltages (V_{GS}) of gallium arsenide-based HEMT 402 and silicon-based MOSFET 404. The output voltage V_{ref} is then applied to the gate of MOSFET 408, which generates a current through diode-connected MOSFET 414. The current through MOSFETs 408 and 414 is mirrored via current mirror 418 to each of MOSFETs 410, 412 and 416. The current passing through MOSFET 416, Iref, is a current that is a function of the threshold voltages of HEMT 402 and MOSFET 404. Because the threshold variation of MOSFET 404 is often insignificant in comparison to the threshold variation of HEMT 402, in many applications Iref may be considered to be a function of the threshold voltage of HEMT 402 alone.

Because the V_{GS}'s are forced to be essentially the same for both HEMT 402 and MOSFET 404 by the feedback configuration of reference circuit 400, and because MOSFETs 410 and 412 are substantially identical, the current through HEMT 402 and MOSFET 404 can only be essentially equal at one non-zero value. This value can be determined by first defining a portion of equation (1) as follows:

$$γ = \frac{{μ}_{n} {C}_{ox}}{2} \cdot \frac{W}{L} \qquad ( 3 )$$

thus, the drain current through the MOSFET may be expressed as:

I_{DS}=γ(V_{GS}−Vₜ)² (4)

or

$${V}_{GS} = \sqrt{\frac{{I}_{DS}}{γ}} + {V}_{t} \qquad ( 5 )$$

Next, equation (2) (i.e., the drain current through the HEMT) can be rewritten as:

$${V}_{GS} = \sqrt{\frac{{I}_{DS}}{β}} + {V}_{p} \qquad ( 6 )$$

Thus, because V_{GS} is forced to be essentially the same for both devices:

$$\sqrt{\frac{{I}_{DS}}{γ}} + {V}_{t} = \sqrt{\frac{{I}_{DS}}{β}} + {V}_{p} \qquad ( 7 )$$

Solving for I_{DS} provides the following:

$${I}_{DS} = \frac{{( {V}_{p} - {V}_{t} )}^{2}}{( \frac{1}{γ} + \frac{1}{β} - \frac{2}{\sqrt{γ β}} )} \qquad ( 8 )$$

which is a single non-zero value if Vₚ is greater than Vₜ, which is the normal case. This is illustrated graphically in FIG. 42, which shows typical current versus voltage curves for the type of devices used for HEMT 402 and MOSFET 404. Curve 502 represents the typical current versus voltage curve for the type of devices used for HEMT 402. Curve 504 represents the typical current versus voltage curve for the type of devices used for MOSFET 404. As can clearly be seen in FIG. 42, there is a single point 510 at which the drain currents of both devices are equal, and that point coincides with where the gate-source voltages are also essentially equal. Thus, as previously described, because the gate-source voltages of both devices are forced to be essentially the same, the drain current for both devices will also be the same.

Reference circuit 400, as described above, includes devices that are fabricated from both a compound semiconductor, such as gallium arsenide (i.e., the HEMT) and silicon (i.e., the MOSFETs). This may be accomplished, in accordance with the principles of the present invention, by providing integrated circuitry which includes a monocrystalline silicon substrate and a monocrystalline compound semiconductor layer, such as gallium arsenide, at least partially overlying the silicon substrate according to the methods described above. The HEMT would then be formed in the monocrystalline compound layer, while the MOSFETs are formed in the monocrystalline silicon substrate. In this manner, all of the circuit components of reference circuit 400 are integrated together on single substrate.

Persons skilled in the art will appreciate that current mirror 418 may be configured such that the mirrored currents are unequal. For example, making the widths of MOSFETs 410 and 412 unequal necessarily results in the currents passing through HEMT 402 and MOSFET 404 being unequal. The unequal currents require that the sizes of HEMT 402 and MOSFET 404 be adjusted to ensure that a common I-V point (like point 510) exists, and that it exists at the desired V_{GS}. For example, if MOSFET 410 is configured to have a larger width than MOSFET 412, the steady-state current through HEMT 402 would be greater than the steady-state current through MOSFET 404. To achieve an identical V_{GS} between the two devices under these conditions, the width of HEMT 402 must be increased, the width of MOSFET 404 must be decreased, or both must occur (depending on the amount of variance in each device, the difference in the steady-state current, and particular IC process features), as compared to their sizes under the equal-current condition.

The use of a silicon substrate and a partial layer of compound semiconductor material is illustrated in FIGS. 43 and 44. FIG. 43 shows a mechanical diagram of an integrated circuit die 600 which includes multiple input/output pins 601. Two specific pins, identified as pins 603 and 605 provide an output connection for V_{ref}, with is provided from pins 603 and 605 to terminals 607 and 609, respectively. For ease of illustration, each of the components in FIGS. 43 and 44 are provided with a reference numeral having the same last two digits as described above with respect to FIG. 41 (for example, HEMT 402 is essentially equivalent to HEMT 602). Thus, the circuit operation previously described with respect to circuit 400 applies equally to the circuit on die 600.

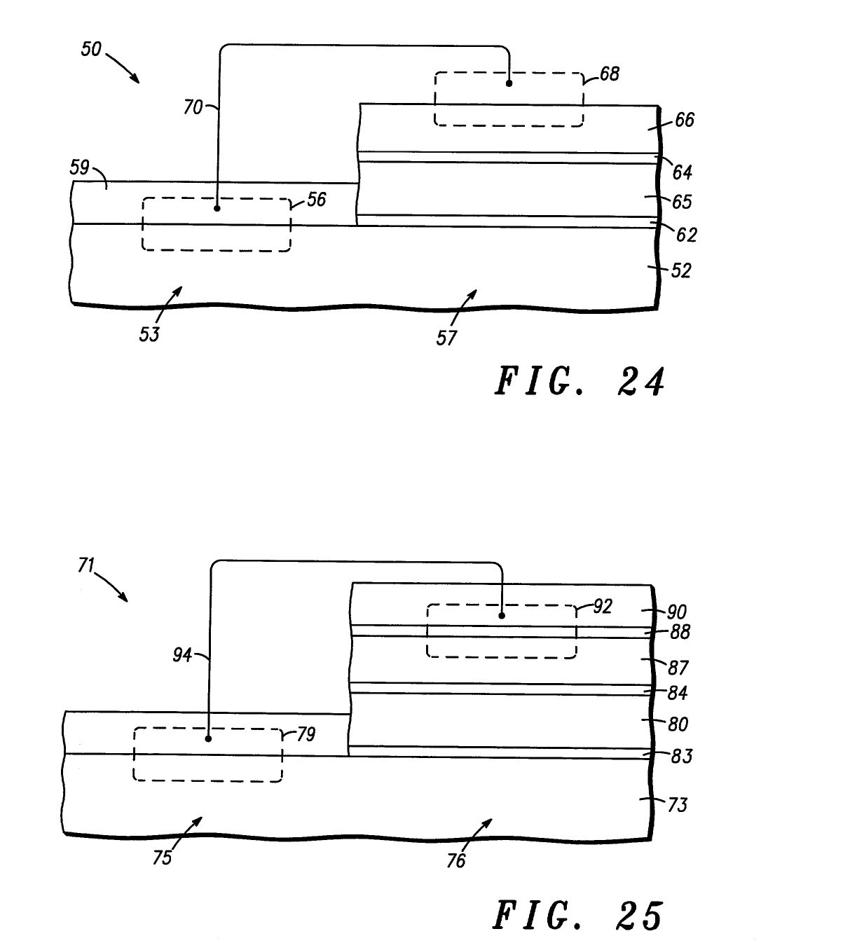

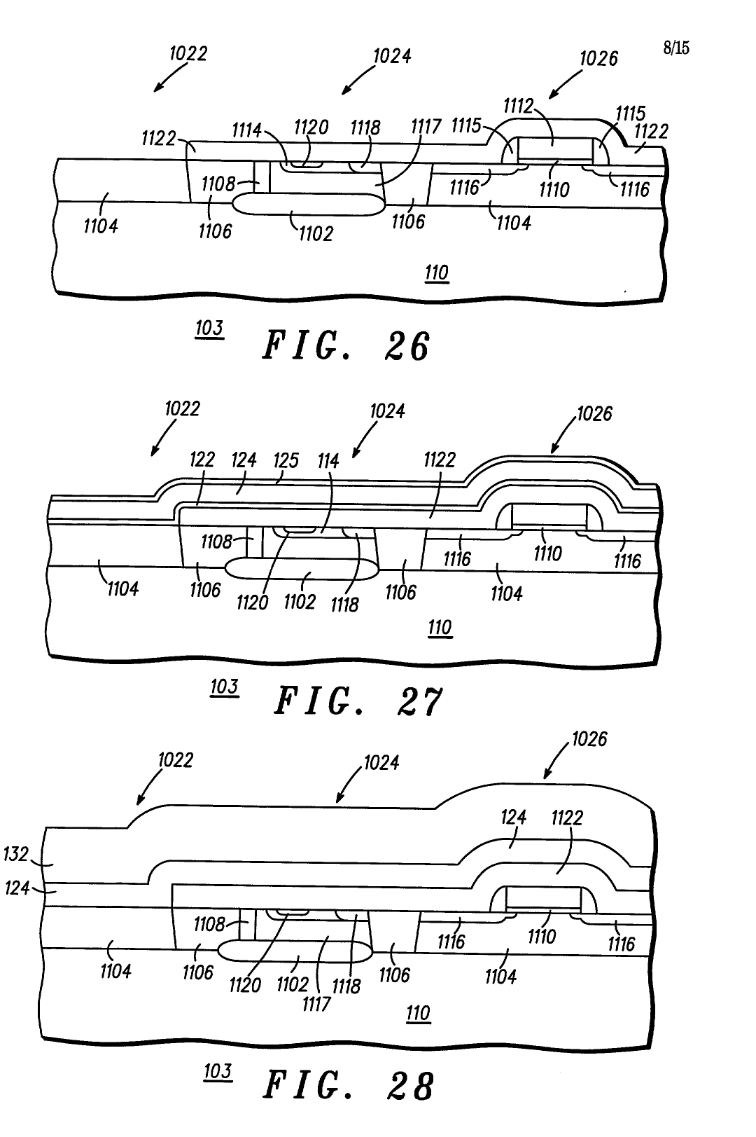

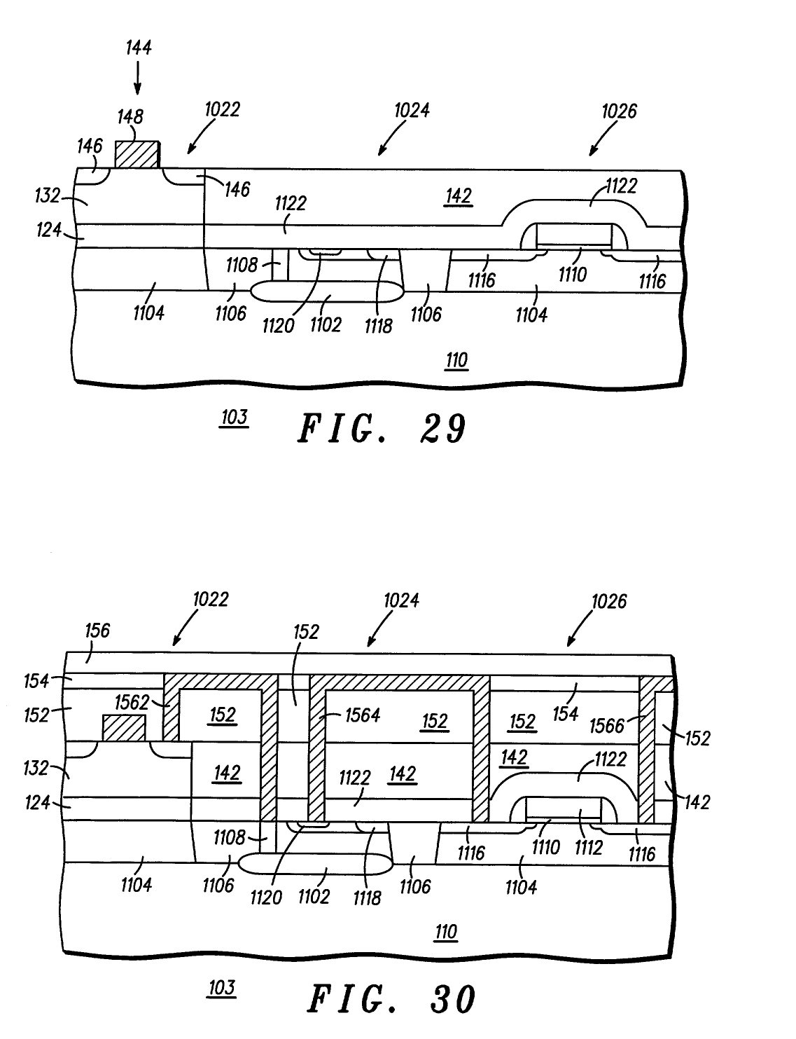

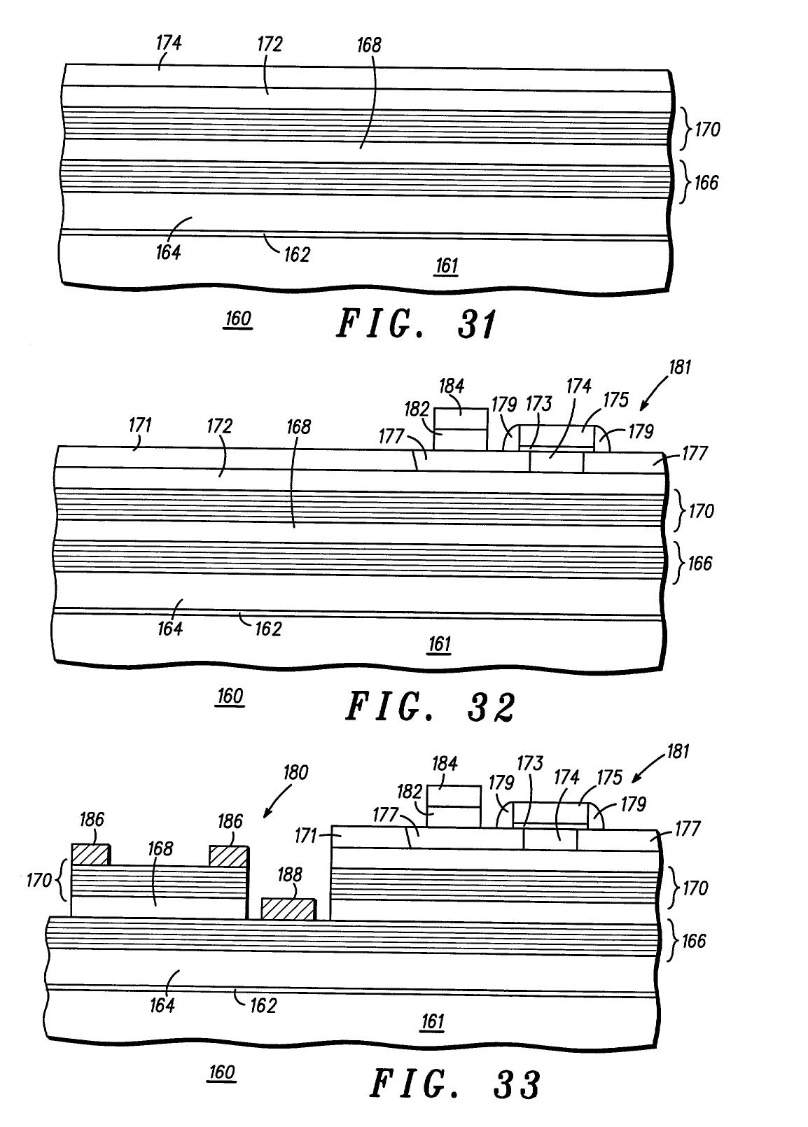

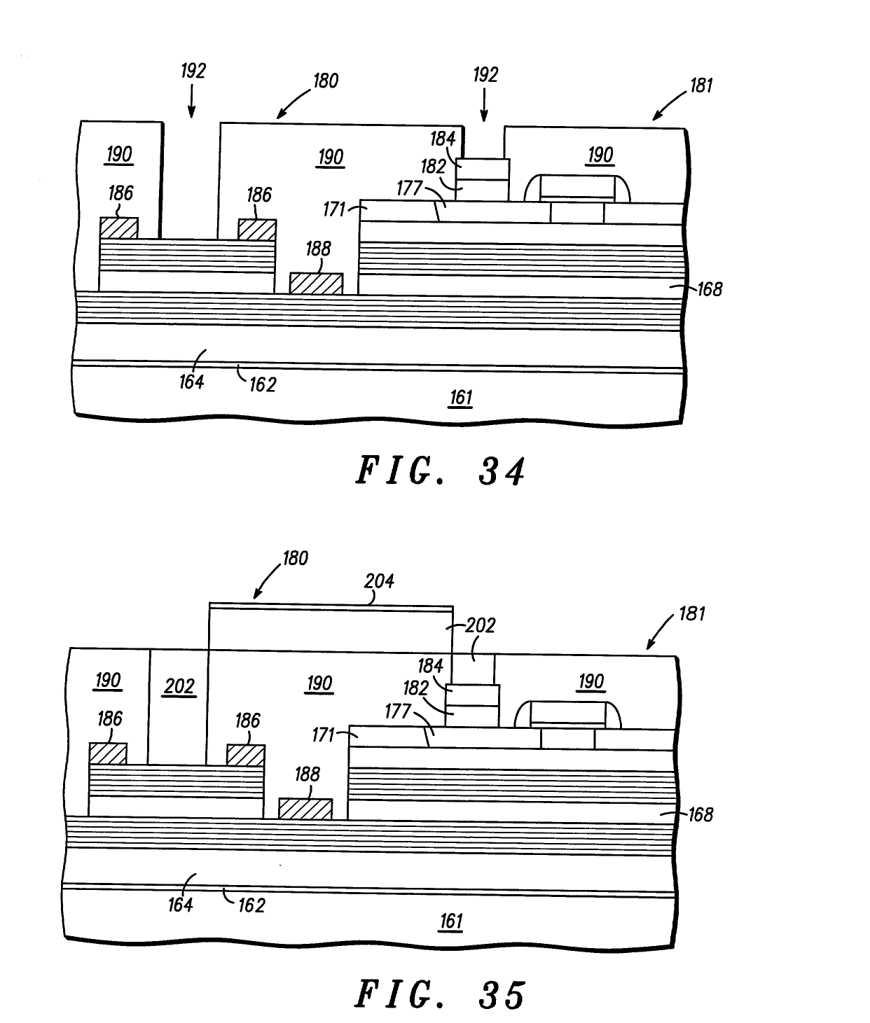

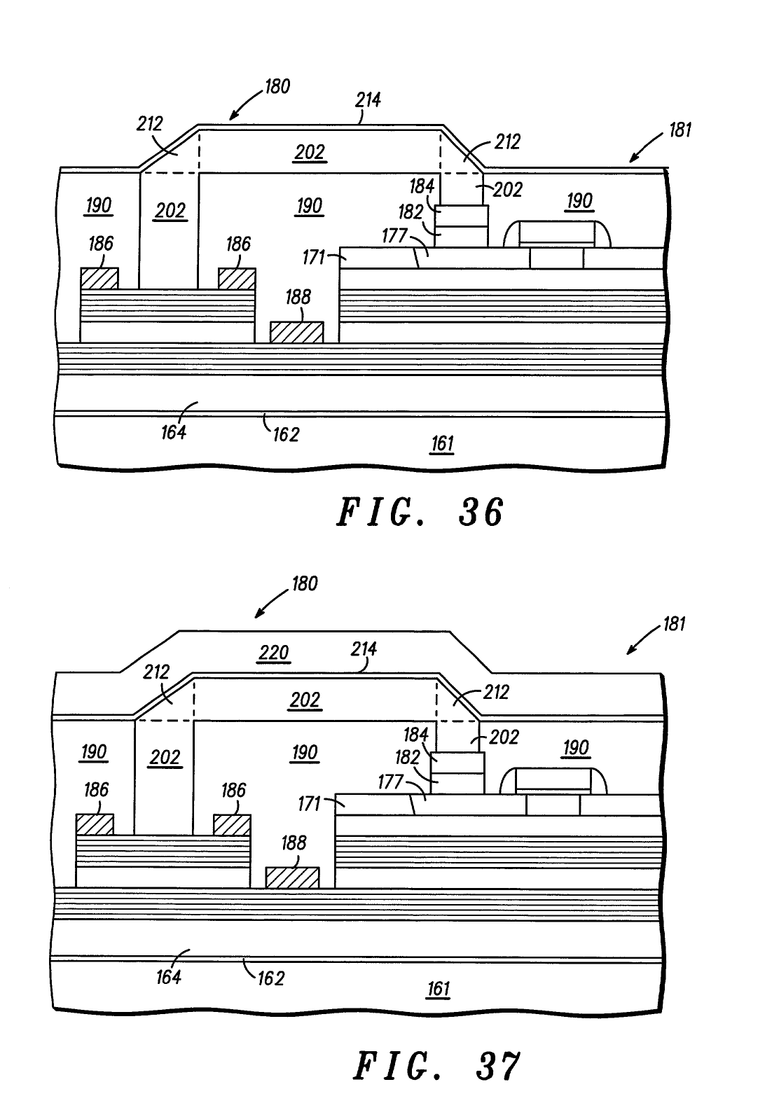

As described above with reference to FIGS. 1-37, the non-silicon based circuit elements may be formed on the silicon substrate by placing them in a compound semiconducting layer formed on top of at least a portion of the semiconductor substrate. In FIGS. 43 and 44, HEMT 602 is formed on a compound semiconductor layer formed on top of silicon substrate 620, while MOSFETs 604, 608, 610, 612, 614 and 616 are formed on semiconductor substrate 620 itself. In addition, error amplifier 606, assuming it is silicon-based, may also be formed on semiconductor substrate 620. Otherwise, at least a portion of error amplifier 606 would be formed on the compound semiconducting layer portion of the circuit.

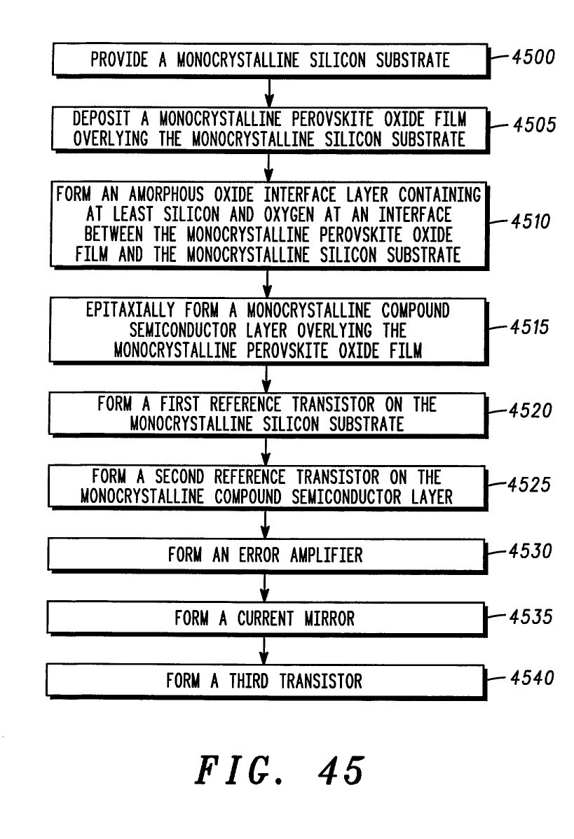

Referring now to FIG. 45, a flow chart shows some steps of a method for method of making a reference circuit on a monocrystalline semiconductor substrate, using the techniques described in this disclosure. Some steps that have been described herein above and some steps that are obvious to one of ordinary skill in the art are not shown in the flow chart, but would be used to fabricate the reference circuit. At step 4500, a monocrystalline silicon substrate is provided, meaning that the substrate is prepared for use in equipment that is used in the next step of the process. A monocrystalline perovskite oxide film is deposited overlying the monocrystalline silicon substrate at step 4505, the film having a thickness less than a thickness of the material that would result in strain-induced defects. An amorphous oxide interface layer is formed at step 4510, containing at least silicon and oxygen at an interface between the monocrystalline perovskite oxide film and the monocrystalline silicon substrate. At step 4515, a monocrystalline compound semiconductor layer is epitaxially formed overlying the monocrystalline perovskite oxide film.

At step 4520, a first reference transistor that provides a first input signal is formed on the monocrystalline silicon substrate. The first reference transistor may be a MOSFET. A second reference transistor that provides a second input signal is formed at step 4525 on the monocrystalline compound semiconductor layer. The second reference transistor may be an enhancement-mode gallium arsenide-based HEMT.

The first and second reference transistors are coupled to receive the first and second currents, respectively, that are a function of a common current. At step 4530, an error amplifier is formed that is coupled to the first and second transistors. The error amplifier compares the first and second input signals and provides an output signal that may be utilized to adjust the common current based, at least in part, on the comparison. At step 4535, a current mirror is formed that receives the common current and provides the first and second currents. A third transistor coupled to the current mirror is formed at step 4540. The third transistor provides an output current that is a function of the output signal.

In addition to the advantages previously described, such as the ability to provide a current Iref that is a function of the threshold voltage of the HEMT, the single substrate that includes both silicon-based and compound semiconductor-based devices enables a circuit designer to include stable, reference circuits for both compound devices and for silicon-based devices on the same integrated circuit as the different devices themselves. This improves the performance of the HEMT circuits by essentially eliminating the variations of HEMT circuit performance due to wafer-to-wafer and die-to-die threshold voltage variations, and reduces the voltage overhead required in conventional circuits.

Persons skilled in the art will appreciate that the advantages of the present invention may be obtained by using other compound semiconductor-based devices instead of the enhancement-mode HEMTs previously described. For example, gallium arsenide-based psuedomorphic HEMTs, indium phosphide MESFETs, or gallium arsenide-based MESFETs may be used to complement the silicon-based MOSFETs.

Moreover, persons skilled in the art will also appreciate that the present invention can be practiced by other than the described embodiments, which are presented for purposes of illustration and not of limitation, and the present invention is limited only by the claims which follow.

The invention claimed is:

1. A reference circuit comprising:
a monocrystalline silicon substrate;
an amorphous oxide material overlying said monocrystalline silicon substrate;
a monocrystalline perovskite oxide material overlying said amorphous oxide material;
a monocrystalline compound semiconductor material overlying said monocrystalline perovskite oxide material;
a first transistor, formed in said monocrystalline silicon substrate, that receives a first current and generates a first input signal;
a second transistor, formed in said monocrystalline compound semiconductor material, that receives a second current and generates a second input signal; and
an error amplifier circuit that compares said first and second input signals and provides an output signal corresponding to said comparison, said first and second transistors being coupled to said error amplifier circuit so that said first and second currents vary based on said output signal.

2. The reference circuit of claim 1, further comprising:
a current mirror coupled to said first and second transistors to provide said first and second currents, said current mirror also being coupled to receive said output signal from said error amplifier circuit.

3. The reference circuit of claim 2 further comprising:
a third transistor coupled to said current mirror that provides an output current that is a function of said output signal.

4. The reference circuit of claim 2, wherein said current mirror comprises:
a third transistor coupled to provide said first current to said first transistor;
a fourth transistor coupled to provide said second current to said second transistor; and
a diode-connected transistor coupled to receive a signal that is a function of said output signal, said third, fourth and diode-connected transistors being coupled together such that current passing through said diode-connected transistor is mirrored to pass through said third and fourth transistors as said first and second currents.

5. The reference circuit of claim 4, wherein said first and second currents are equal.

6. The reference circuit of claim 4, wherein said first and second currents are unequal.

7. The reference circuit of claim 4 further comprising:
a fifth transistor coupled to said current mirror that provides an output current that is a function of said output signal.

8. The reference circuit of claim 1, wherein said second transistor is a high electron mobility transistor (HEMT).

9. The reference circuit of claim 1, wherein said first transistor is a MOSFET.

10. The reference circuit of claim 8, wherein said HEMT is an enhancement-mode gallium arsenide-based HEMT.

11. The reference circuit of claim 8, wherein said HEMT is a pseudomorphic HEMT.

12. The reference circuit of claim 1, wherein said second transistor is a MESFET.

13. The reference circuit of claim 1, wherein said monocrystalline compound semiconductor layer is a layer of gallium arsenide.

14. An integrated monolithic semiconductor reference circuit comprising:
at least a first transistor, formed on a monocrystalline semiconductor substrate, that receives a first current;
at least a second transistor, formed on a compound semiconductor layer that is formed on at least a portion of said substrate, that receives a second current, said first and second transistors being coupled together to receive first and second currents that are functions of a common current; and
a comparison circuit coupled to said first and second transistors that provides an output signal corresponding to a voltage difference between said first and second transistors.

15. The reference circuit of claim 14, further comprising:
a current mirror circuit coupled to receive a signal that is a function of said output signal, and coupled to said first and second transistors to provide said first and second currents.

16. The reference circuit of claim 15 further comprising:
a third transistor coupled to said current mirror that provides an output current that is a function of said output signal.

17. The reference circuit of claim 15, wherein said current mirror circuit comprises:
a diode-connected transistor coupled to receive said signal that is a function of said output signal;
a third transistor coupled to provide said first current to said first transistor; and
a fourth transistor coupled to provide said second current to said second transistor.

18. The reference circuit of claim 17 further comprising:
a fifth transistor coupled to said current mirror circuit that provides an output current that is a function of said output signal.

19. The reference circuit of claim 14, wherein said first transistor comprises a MOSFET.

20. The reference circuit of claim 14, wherein said second transistor comprises a high electron mobility transistor (HEMT).

21. The reference circuit of claim 20, wherein said HEMT comprises an enhancement-mode gallium arsenide-based HEMT.

22. The reference circuit of claim 20, wherein said HEMT comprises a pseudomorphic HEMT.

23. The reference circuit of claim 14, wherein said second transistor comprises a MESFET.

24. The reference circuit of claim 17, wherein said current mirror comprises a plurality of MOSFETs formed on said monocrystalline semiconductor substrate.

25. A method of making a reference circuit on a monocrystalline semiconductor substrate comprising:
providing a monocrystalline silicon substrate;
depositing a monocrystalline perovskite oxide film overlying the monocrystalline silicon substrate, the film having a thickness less than a thickness of the material that would result in strain-induced defects;
forming an amorphous oxide interface layer containing at least silicon and oxygen at an interface between said monocrystalline perovskite oxide film and said monocrystalline silicon substrate;
epitaxially forming a monocrystalline compound semiconductor layer overlying said monocrystalline perovskite oxide film;
forming a first reference transistor on said monocrystalline silicon substrate that receives a first current and generates a first input signal;
forming a second reference transistor on said monocrystalline compound semiconductor layer that receives a second current and generates a second input signal, said first and second reference transistors being coupled to receive first and second currents, respectively, that are a function of a common current; and
forming an error amplifier coupled to said first and second transistors, said error amplifier comparing said first and second input signals and providing an output signal that may be utilized to adjust said common current based, at least in part, on said comparison.

26. The method of claim 25, wherein said error amplifier is formed on said monocrystalline silicon substrate.

27. The method of claim 25 further comprising: forming a current mirror that receives said common current and provides said first and second currents.

28. The method of claim 27 further comprising: forming a third transistor coupled to said current mirror, said third transistor providing an output current that is a function of said output signal.

29. The method of claim 25, wherein said layer of compound semiconductor material comprises a layer of gallium arsenide.
